(19) United States
(12) Patent Application Publication
(10) Pub. No.: US 2012/0028025 A1
(43) Pub. Date: Feb. 2, 2012

(54) ELECTRICAL OR ELECTRONIC COMPOSITE COMPONENT AND METHOD FOR PRODUCING AN ELECTRICAL OR ELECTRONIC COMPOSITE COMPONENT

(75) Inventors: Daniel Wolde-Giorgis, Leinfelden-Echterdingen (DE); Erik Sueske, Reutlingen (DE); Martin Rittner, Freiberg (DE); Erik Peter, Ludwigsburg (DE); Herbert Schwarzbauer, Muenchen (DE); Michael Guenther, Stuttgart (DE)

(73) Assignees: SIEMENS AKTIENGESELLSCHAFT, Munchen (DE); ROBERT BOSCH GMBH, Stuttgart (DE)

(21) Appl. No.: 13/141,756

(22) PCT Filed: Dec. 18, 2009
(86) PCT No.: PCT/EP2009/067498

§ 371 Date: Sep. 29, 2011

(30) Foreign Application Priority Data
Dec. 23, 2008 (DE) 10 2008 055 137.6

(51) Int. Cl. B32B 3/26; H05K 13/00

(52) U.S. Cl. 428/304.4; 29/592.1

(57) ABSTRACT

The invention relates to an electrical and electronic composite component (1), comprising a first joining partner (2) and at least one second joining partner (3). The invention provides for an openly porous sintered shaped part (6, 7) to be accommodated between the first and the second joining partners (2, 3), said sintered shaped part being sintered by sintering by means of sintering paste with the first and the second joining partners (2, 3). The invention furthermore relates to a production method.

### BACKGROUND OF THE INVENTION

The invention relates to an electrical or electronic composite component and a method for producing an electrical or electronic composite component.

The joining of power semiconductors, such as JFETs, MOSFETs, IGBTs, or diodes to a circuit carrier of a power electronic module and also the joining of the circuit carrier to a base plate/heat sink are typically carried out by means of soldering technology. Due to new EU legislation, the use of leaded solder alloys (Sn63Pb37 and Sn5pb95) will be prohibited in the future. Lead-free solder alloys based on SnAg Cu can be used only limitedly as substitute alloys because said alloys have limited reliability, particularly under passive and active loads caused by changes in temperature. Alternative refractory solders are either too brittle to manipulate (Bi97.5Ag2.5) or too expensive (Au80Sn20) to be used as substitute alloys.

As an alternative, high temperature resistant as well as highly reliable joining technology, the direct sintering of joining partners by means of sintering paste is known from prior art. This technology is designated as low temperature connection technology (NTV). Two different options for executing this technology are in use, namely the sintering of silver metal flakes as is described in the European patent publication EP 2 426 26 B1 as well as the sintering of silver metal nano particles as is described in the patent publication of the World Intellectual Property Organization WO 2005/079353 A2. The sintering operation contrasts a soft-solder procedure by virtue of the fact that the (sinter) particles do not enter the liquid phase, i.e. they do not melt.

When sintering silver metal flakes, atmospheric oxygen for burning off wax lubricants requires a temperature of approximately 240 EC as well as a high operating pressure of approximately 40 MPa. The sintering of silver metal nano particles provides the option requiring considerably less pressure, which ranges from 100 kPa to 5 MPa, to carry out the sintering operation. As is the case when sintering silver metal flakes, oxygen as well as an operating temperature of approximately 280 EC is required for sintering nano particles. The known silver metal-nano particle paste formulation furthermore contains an even higher proportion of organic additives, as, for example solvents and/or adhesive agents, than paste formulations based on silver metal flakes. In methods known from prior art, sintering paste is directly applied to the first and/or the second joining partner, whereupon the joining partners are pressed against one another under the influence of temperature. When executing the operation using sinter paste, the difficulty is that large gas volumes have to be exchanged through the sintering layer and, therefore, oxygen must reach the joining locations, and solvents as well as burned/oxidated organic material must have the possibility to escape. Especially under the desired low operating pressures, this leads to more severe cracking, particularly with joints covering a large surface area.

### SUMMARY OF THE INVENTION

The thought at the basis of the invention is to propose an electronic or electrical composite component as well as a production method for a composite component of this kind, in which firstly leaded solders are not used and secondly crack formations during sintering (joining) can be avoided.

This aim is met with respect to the electrical or electronic composite component of the invention and with respect to the production method of the invention. All combinations of at least two of the features disclosed in the description, the claims and/or the figures fall within the scope of the invention. In order to avoid repetition, features disclosed pursuant to the device shall apply to and be claimable as features disclosed pursuant to the method. Features disclosed pursuant to the method shall likewise apply to and be claimable as features disclosed pursuant to the device.

The thought at the basis of the invention is not to directly sinter two joining partners by means of sintering paste, i.e to directly fix together, but to fixedly connect the joining elements by sintering by means of sintering paste using a previously produced sintered shaped part having a continuously open porosity. The thickness extension of the sintered shaped part (sintered foil) being used is thereby preferably between approximately 10:m and approximately 300:m or more in the stacking direction. Such a sintered shaped part has the advantage of comprising gas channels for the aeration and ventilation of the emerging joint, which are already integrated and stable with respect to the joining partners in the subsequent sintering operation. In contrast to the direct joining of joining partners to one another by the use of silver paste, the employment of a composite component embodied according to the concept of the invention or a production method according to the invention furthermore means that only a reduced gas exchange is necessary, which will then additionally take place considerably more effectively by means of the already predefined paths in the sintered shaped part. A further advantage of providing a porous sintered shaped part between the joining partners is that said sintered shaped part, particularly in the case of joining partners, which comprise the identical material as said sintered shaped part, being connected to the same, already has the identical characteristics as the emerging joint. Said characteristics include a high electrical and thermal conductivity, a large porosity and as a result a comparatively low modulus of elasticity. The use of a porous sintered shaped part as an insert part or union end has a positive effect on the sintering operation for joining the joining partners to said sintered shaped part, particularly if joining partners having large surface areas, such as silicone power semiconductors and circuit carriers or circuit carriers and heat sinks, are connected by sintering with said sintered shaped part. A further advantage of employing a sintered shaped part is that the freedoms in designing the joint are enhanced because said sintered shaped part can have a larger surface than at least one of the joining partners, preferably than both joining partners, and/or said joining partners can be spaced considerably further apart from one another than when executing the operation according to prior art, i.e. when directly sintering said joining partners by means of sintering paste. The advantage consists particularly of an increased resistance to changes in temperature.

The invention can be used in a plurality of electrical and/or electronic applications. The inventive implementation in power electronic modules is particularly preferred, which, for example, are required for many forms of energy conversion, in particular mechanical/electrical (generator, rectifier), electrical/electrical (converter, AC/AC, DC/DC) as well as electrical/mechanical (electrical drives, inversion). Suitably embodied power electronic modules for rectification can furthermore be employed in a motor vehicle generator, for controlling electrical drives, for DC/DC converters, for pulse width modulation, for hybrid/fuel cell/electric drives as well as for Photovoltaic inverters etc. Additionally or alternatively, individual components having higher dissipation losses, particularly on the stamped grids of discrete packages, can be joined according to the invention. Said components can then, for example, be used as completely lead-free solutions in printed circuit board technology.

The implementation of the invention is particularly preferred in superstructures having semiconductor laser diodes or in applications with MEMS and sensors, in particular for high temperature applications. Additional areas of usage are semiconductor light-emitting diodes and high frequency semiconductors for radar applications.

An embodiment of the composite component is especially preferred, in which the sintered shaped part is produced from silver metal, particularly from silver metal flakes, and/or comprises silver metal, particularly silver metal flakes. Sintered shaped parts produced from silver metal or comprising silver metal are advantageous with regard to the high electrical and thermal conductivity thereof. Moreover, silver is suited to implementing a continuously open porosity that forms gas channels. It is furthermore preferred if a sintered shaped part constructed in this manner is joined to at least one of the joining partners, preferably with both of said joining partners, by means of silver sintering paste. It is very particularly preferred for the sintered shaped part to be produced in a silver sintering operation, which is preferably executed such that said sintered shaped part or a sintered part, which is subsequently divided up into a plurality of sintered shaped parts, neither links together with the stamp being employed nor with the die plate being employed during the associated pressing operation. This can, for example, be implemented by virtue of said stamp and said die plate having top surfaces which are oxide coated, as is described in the dissertation by Mertens, on pages 78 and 79, ISBN 3-18-336521.

Provision is advantageously made in a modification to the invention for the first and/or the second joining partner to be sintered with the sintered shaped part, particularly by means of sintering paste. Because the porosity develops uniformly in the finished combined sintered joint consisting of said sintered shaped part and the sintering paste, substantial material constants, such as mechanical moduli as well as electrical and/or thermal conductivity, can be more uniformly represented than this was possible in prior art. The sintering paste, particularly the silver sintering paste, is preferably applied to the joining partners as well as to the sintered shaped part, which is then serving as a deposit, or alternatively only on one side of said sintered shaped part and only on one joining partner. The organic components are removed from the sintering paste during the joining operation by means of temperature and if need be the application of pressure. A removal of the evaporated or oxidized organic components is ensured by the open porosity. In the further course of the joining operation, a sintering of the sintering paste, particularly of the silver sintering paste, with the respective joining partner and the porous silver sintered part (silver preform) takes place. As a result, further organic constituents are oxidized. The oxidation products and the required oxygen are transported by the pre-sintered silver shaped part.

There are many different options, which lead to many different composite components, with regard to the embodiment of the first and second joining partners. The first joining partner very preferably relates to an electronic component, preferably a semiconductor component, very particularly preferably to a power semiconductor, which can be connected via a sintered shaped part to the second joining part, in particular a circuit carrier (printed circuit board). It is likewise possible to connect a first joining partner, which is embodied as a circuit carrier, to a second joining partner, which is preferably embodied as a base plate, particularly consisting of copper, via a sintered shaped part. The copper base plate preferably serves as a heat sink or is connected to a cooling element serving as a heat sink. It is also possible to connect the cooling element (first joining partner) and the base plate (second joining partner) to one another via a sintered shaped part. It is furthermore possible to connect, i.e. (to contact) at least one bonding wire or at least one bonding ribbon to a further joining partner, particularly an electronic component, preferably a semiconductor component, especially a power semiconductor component or a circuit carrier (electrical component), via a sintered shaped part. In this case, the sintered shaped part acts to increase reliability. It is likewise possible that the first joining partner relates, for example, to an electrical component, particularly a punched grid (wire grid), which can be connected to a second joining partner, in particular a circuit carrier, more precisely to a metal of the circuit carrier, via a sintered shaped part. Up until now punched grids have been directly soldered to a printed circuit board (circuit carrier), whereby enclosed pores/cavities (blowholes) result. Moreover, the joining gap fluctuates sharply when executing the operation according to prior art, so that a reliable joining is not ensured in each case or cannot be guaranteed under stress caused by temperature and changes in temperature. Additional combinations of the first and second joining partner ensuing from the claims can be implemented, wherein the joining partners can be connected to the sintered shaped part by sintering by means of sintering paste.

The use of sintered shaped parts is not limited to composite components having only two joining partners. Thus, it is, for example, conceivable to produce a composite component having two or more sintered shaped parts, wherein in each case at least two joining partners are fixed together via a sintered shaped part. In this way, a sandwich-like construction comprising three or more joining partners can be produced, wherein the joining partners and the sintered shaped parts are preferably stacked in a stacking direction. A second joining partner formed from a power semiconductor can thus, for example, be connected on both sides to a circuit carrier forming a first or a second joining partner via in each case a sintered shaped part; thus enabling the power semiconductor to be accommodated in a sandwich-like manner between the circuit carriers, wherein in each case a sintered shaped part is situated between a circuit carrier and the power semiconductor. The sandwich-like construction does not absolutely have to be realized in one process step but can, for example, be produced in two or in a plurality of steps.

The invention also leads to a method for producing an electrical or electronic composite component, preferably a composite component embodied as previously described. The core of the method consists of sintering at least two joining partners with an openly porous sintered shaped part (sintered foil) by means of sintering paste, wherein it is possible to use the same sintering paste or alternatively different sintering pastes for both joining partners. In so doing, the joining partners are very specifically sintered onto two sides of the sintered shaped part facing opposite one another. The advantage of the method according to the invention is that gases occurring during the joining operation (sintering operation) of the joining partners escape through the continuously open, porous structure of the sintered shaped part and when needed gases such as oxygen can be fed to the joining locations. The gas discharge and the gas supply preferably take place from the lateral direction, i.e. transversely to the stacking direction of the joining partners.

A modified embodiment of the method is very particularly preferred, in which the sintered shaped part (sintered foil) is produced by means of a punch or die plate before the joining operation. As a result, it is possible to directly sinter said sintered shaped part or to extract, e.g. punch out, saw out or cut out, said sintered shaped part from a large sintered part following completion of the sintering operation.

### BRIEF DESCRIPTION OF THE DRAWINGS

Further advantages, features and details of the invention ensue from the following description of preferred exemplary embodiments as well as with the aid of the drawings.

Said drawings depict:

FIG. 1 a power electronic composite component (in this instance a power electronic assembly, module),

FIG. 2 a partial depiction of a sintered shaped part for connecting two joining partners together,

FIG. 3 a production process, which is schematically depicted, for producing an electrical or electronic composite component comprising two joining partners and

FIG. 4 a production process in schematic depiction for producing an electrical or electronic composite component with three joining partners and two sintered shaped parts.

### DETAILED DESCRIPTION

Like elements and elements having the same function are denoted with the same reference numerals.

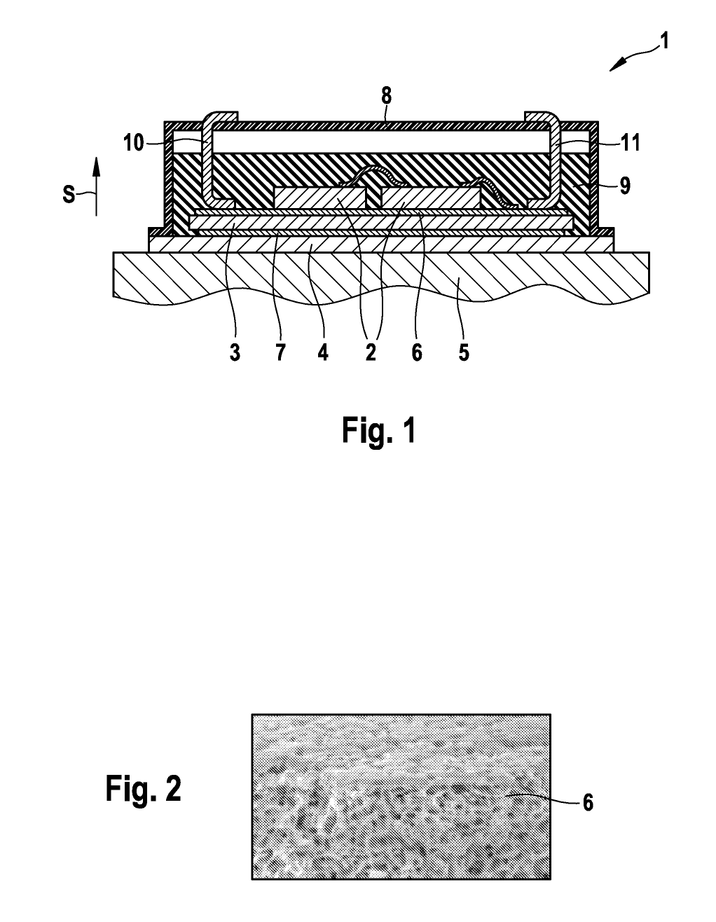

FIG. 1 shows an electronic composite component 1. This comprises a first joining partner 2, a second joining partner 3 as well as a third joining partner 4. In the exemplary embodiment shown, the first joining element relates to a power semiconductor component, in this case an IGB transistor. The second joining partner 3 relates to a circuit carrier and the third joining partner 4 to a base plate consisting of copper. The base plate of copper is in turn fixed to a cooling element 5 (heat sink).

A sintered shaped part 6 having a thickness extension of approximately 50:m in a stacking direction S is disposed between the first joining partner 2 and the second joining partner 3. Said first joining partner 2 and said second joining partner 3 are fixed on two sides of the sintered shaped part 6, which face opposite one another, by sintering by means of silver sintering paste. Said sintered shaped part 6 is also formed of silver sintered material. Said second joining partner 3 is in turn connected to the third joining partner 4 via a further sintered shaped part 7, wherein said third joining partner 4 as well as the second joining partner 3 are in each case fixedly connected to the sintered shaped part 7 with sintering paste.

In the exemplary embodiment shown, the third joining partner 4 is directly soldered to the cooling element 5. As an alternative (not depicted), a sintered shaped part can also be provided between said third joining partner and said cooling element 5, with which said third joining partner 4 and said cooling element 5 are fixed by sintering by means of sintering paste.

As can be further seen in FIG. 1, a plastic housing 8 is fixed to the third joining partner, which is formed from the base plate, said plastic housing enclosing the stack arrangement comprising the first and the second joining partner 2, 3 as well as the sintered shaped part 6. The so-called stack arrangement is surrounded by an elastic protective mass 9. Connecting wires 10, 11 are fed through said protective mass 9 up to the exterior side of the housing 8, said wires being fixed to the second joining partner 3 (circuit carrier), contacting the former, via said sintered shaped part 6.

FIG. 2 shows the construction of a sintered shaped part 6, which is produced from silver metal flakes. The continuously open porosity can be seen therein. Said porosity forms gas passage channels, through which the gases can flow away from the joining locations in the outward direction or to the joining locations during a sintering operation. The gases preferably move laterally out of the pores, i.e. transversely to the stacking direction S (cf. FIG. 1), whereby a crack formation resulting from a sintering operation by means of sintering paste is avoided.

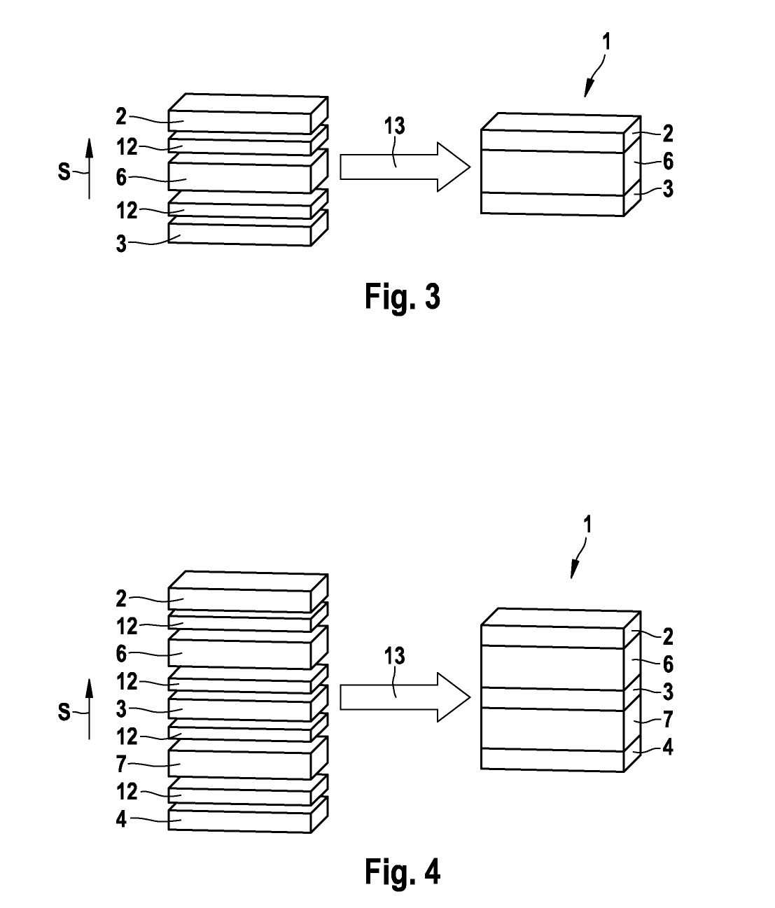

In an intensively schematized manner, FIG. 3 shows the production process for producing an electrical or electronic composite component 1, which in the drawing plane is depicted on the right side. The latter comprises a first joining partner 2, which is depicted at the top in the drawing plane, and a second joining partner 3, which is depicted at the bottom in the drawing plane, said joining parts accommodating a sintered shaped part 6 between them in a sandwich-like manner. The first joining part 2 relates, for example, to a chip and the second joining partner 3 to a circuit carrier. As an alternative thereto, it is conceivable for said first joining partner 2 to relate to a circuit carrier and for said second joining partner to a base plate, particularly consisting of copper, and/or a cooling element. Further combinations of said first and second joining partner 2, 3 ensuing from the claims can be alternatively implemented. In the exemplary embodiment shown, sintering paste 12, in this case silver sintering paste, has been initially applied to both face sides of the sintered shaped part 6 as a deposit. After stacking in the stacking direction S, the said joining partners 2, 3, the sintered shaped part 6 as well as the sintering paste 12 are subjected to a sintering operation. This sintering operation relates to the second sintering operation of said sintered shaped part 6. The gas exchange for the sintering of the sinter paste 12 can take place over the entire porous volume of said sintered shaped part 6.

Sinterings between the joining partners 2, 3 typically do not display the same porosity on the edge region (particularly on a chip edge) as in an interior region. This is attributed to the fact that no isostatic pressure conditions can be built up there and consequently the sintering takes place locally with less compression. In the event that sintering paste is used alone, it is conceivable that additionally a bead-shaped bulge in the edge region of the joining zones arises.

An alternative joining operation can also be explained with the aid of FIG. 3. The second joining partner 3 can thus, for example, relate to a circuit carrier, particularly the metal of a circuit carrier, typically copper or a copper alloy, and the first joining partner 2 to a punched grid, typically consisting of copper or a copper alloy. Sintering paste can, for example, be printed or dispensed onto said second joining partner 3. After that the sintered shaped part 6 is placed thereupon. If needed, the sintered shaped part 6 can already include a sintering paste deposit on the opposite side for the first joining partner 2 (punched grid). As an alternative, the sintering paste is applied as a sintering paste deposit in a subsequent operation, for example, dispensing. The first joining partner is subsequently deposited onto the sintering paste and delivered to a sintering operation (pressure+temperature). The porous structure of the sintered shaped part 6 inherently provides sufficient options for the degassing of the sintering paste system.

FIG. 4 shows a multi-parted electrical or electronic composite component on the right side as seen in the drawing plane. In total, said component comprises three joining partners 2, 3, 4, wherein a sintered shaped part 6, 7 is disposed between in each case two joining partners 2, 3; 3, 4. The first and the third joining partners 2, 4 can, for example, in each case relate to a circuit carrier and the central, i.e. inner, joining partners 3 in each case to a power semiconductor. The sandwich-like construction does not absolutely have to be joined in a common sintering operation. On the contrary, a two step execution of the operation can also be implemented. In so doing, the first joining partner 1, the sintered shaped part 6 and the second joining partner 3 are, for example, initially connected and then subsequently the third joining partner 4 is connected; or alternatively said third joining partner 4, the further sintered shaped part 7 and the second joining partner 3 are connected and then the first joining partner 2 is connected downstream.

1. An electrical or electronic composite component, comprising a first joining partner (2) and at least one second joining partner (3), characterized in that an openly porous sintered shaped part (6, 7) is accommodated between the first and the second joining partners (2, 3), said sintered shaped part being sintered by sintering by means of sintering paste with said first and said second joining partners (2, 3).

2. A composite component according to claim 1, characterized in that the sintered shaped part (6, 7) is produced from silver metal, and/or comprises silver metal.

3. A composite component according to claim 1, characterized in that the first joining partner (2) is an electronic component.

4. A composite component according to claim 1, characterized in that the second joining partner (3) is an electronic component.

5. A composite component according to claim 1, characterized in that a further sintered shaped part (7) is accommodated between the first joining partner (2) and a third or fourth joining partner (4) and/or a further sintered shaped part (7) is accommodated between the second joining partner (3) and a third or a fourth joining partner (4).

6. A composite component according to claim 5, characterized in that the third and/or the fourth joining partner (4) are/is an electronic component.

7. A method for producing an electrical or electronic composite component (1), wherein a first and a second joining partner (2, 3) are fixedly sintered by means of sintering paste with an openly porous sintered shaped part (6, 7).

8. A method according to claim 7, characterized in that the first and the second joining partner (2, 3) are fixed to two sides of the sintered shaped part (6, 7) which face away from one another.

9. A method according to claim 7, characterized in that the first and/or the second joining partner (2, 3) are/is sintered by means of sintering paste (12, 13) with the sintered shaped part (6) in a common sintering step under the influence of temperature and/or pressure.

10. A method according to claim 9, characterized in that prior to sintering, the sintering paste (12, 13) is applied to the first joining partner (2) and/or the second joining partner (3) and/or the sintered shaped part (6, 7).

11. A method according to claim 7, characterized in that a further sintered shaped part (7) is disposed between the first joining partner (2) and a third or fourth joining partner (4), and/or a further sintered shaped part (7) is disposed between the second joining partner (3) and a third or a fourth joining partner (4).

12. A method according to claim 11, characterized in that the sintering of the further sintered shaped part (7) with the first or the second joining partner (2, 3) as well as the sintering of the sintered shaped part (6, 7) with said first and said second joining partner (2, 3) is carried out in a common process step or in separate process steps.

13. A method according to claim 7, characterized in that a sintered part is separated into a plurality of sintered shaped parts (6, 7).

14. A composite component according to claim 1, characterized in that the sintered shaped part (6, 7) is produced from silver metal flakes, and/or comprises silver metal flakes.

15. A composite component according to claim 1, characterized in that the first joining partner (2) is a power semiconductor component, or a metallization of a circuit carrier, or a punched grid or a bonding wire or a bonding ribbon or a base plate.

16. A composite component according to claim 1, characterized in that the second joining partner (3) is a power semiconductor component, or a metallization of a circuit carrier, or a base plate consisting of copper, or a cooling element (5).

17. A composite component according to claim 1, characterized in that a further sintered shaped part (7) is accommodated between the first joining partner (2) and a third or fourth joining partner (4) and/or a further sintered shaped part (7) is accommodated between the second joining partner (3) and a third or a fourth joining partner (4), said sintered shaped part being sintered by means of sintering paste with the adjacent joining partners (2, 3, 4).

18. A composite component according to claim 17, characterized in that the third and/or the fourth joining partner (4) are/is a power semiconductor component, or a metallization of a circuit carrier, or a base plate consisting of copper, or a cooling element (5).

19. A method for producing an electrical or electronic composite component (1), according to claim 1, wherein a first and a second joining partner (2, 3) are fixedly sintered by means of sintering paste with an openly porous sintered shaped part (6, 7).

20. A method according to claim 9, characterized in that prior to sintering, the sintering paste (12, 13) is printed or dispensed on the first joining partner (2) and/or the second joining partner (3) and/or the sintered shaped part (6, 7).

21. A method according to claim 19, characterized in that a further sintered shaped part (7) is disposed between the first joining partner (2) and a third or fourth joining partner (4), and/or a further sintered shaped part (7) is disposed between the second joining partner (3) and a third or a fourth joining partner (4), said sintered shaped part being sintered by means of sintering paste (12, 13) with the adjacent joining partners (2, 3, 4).
